(19) United States
(12) Patent Application Publication
(10) Pub. No.: US 2026/0244042 A1
(43) Pub. Date: Aug. 20, 2026

(54) ACOUSTIC RESONATOR, MODULATOR, AND ACOUSTO-OPTIC MODULATOR

(71) Applicant: Nippon Telegraph and Telephone Corporation, Tokyo (JP)

(72) Inventors: Megumi Kurosu, Tokyo (JP); Daiki Hatanaka, Tokyo (JP); Hiroshi Yamaguchi, Tokyo (JP); Yoshitaka Taniyasu, Tokyo (JP); Hajime Okamoto, Tokyo (JP)

(21) Appl. No.: 18/872,195

(22) PCT Filed: Aug. 5, 2022
(86) PCT No.: PCT/JP2022/030068

§ 371 Date: Dec. 5, 2024

(51) Int. Cl. G02F 1/125; G02F 1/00; G02F 1/015; H10N 30/20; H10N 30/85

(52) U.S. Cl. CPC G02F 1/125; G02F 1/0072; G02F 1/0151; H10N 30/20; H10N 30/85; G02F 2201/128

(57) ABSTRACT

This acoustic resonator includes a first electrode, a piezoelectric body, and a second electrode. The first electrode is made of a semiconductor doped with impurities. The piezoelectric body is made of a piezoelectric semiconductor and is formed on the first electrode. The piezoelectric semiconductor is, for example, a nitride semiconductor. The second electrode is formed on the piezoelectric body. The second electrode can be made of a metal or a semiconductor doped with impurities.

### CROSS-REFERENCE TO RELATED APPLICATIONS

This application is a national phase entry of PCT Application No. PCT/JP2022/030068, filed on Aug. 5, 2022, which application is hereby incorporated herein by reference.

### TECHNICAL FIELD

The present invention relates to a bulk acoustic resonator, a modulator, and an acousto-optic modulator.

### BACKGROUND

A bulk acoustic resonator has a structure in which a piezoelectric body is sandwiched between two metal electrodes. In this case, a piezoelectric body is formed on one metal electrode, and the other metal electrode is formed on the formed piezoelectric body. However, in forming a piezoelectric film on one of the metal electrodes, it has been difficult to perform epitaxial growth, which enables high-quality film formation. For this reason, usually, a piezoelectric film is formed on one of the metal electrodes using a sputtering method.

### CITATION LIST

### Non Patent Literature

NPL 1 J. Wu et al., “A New Class of High-Overtone Bulk Acoustic Resonators Using Lithium Niobate on Conductive Silicon Carbide,” IEEE Electron Device Letters, vol. 42, No. 7, pp. 1061-1064, 2021.

### SUMMARY

### Technical Problem

However, when a piezoelectric film is formed on a metal electrode using a sputtering method, epitaxial growth for single crystal growth is difficult, and there is a problem in that the piezoelectric body becomes a polycrystalline thin film, resulting in a decrease in film quality. Further, in order to epitaxially grow a piezoelectric body on a metal electrode using a sputtering method, it is necessary to grow a seed layer on the metal electrode, which complicates the manufacturing process.

Furthermore, in recent years, bulk acoustic resonators have been produced by laminating a lithium niobate single crystal onto a semiconductor substrate doped with impurities instead of a metal lower electrode (NPL 1). This technique has the problem that there is a likelihood that foreign matter may be mixed in or cavities may be generated at an interface between the lithium niobate single crystal and the semiconductor layer, which may reduce the piezoelectric efficiency and Q value.

Embodiments of the present invention have been made to solve the above-mentioned problems, and an object of the present invention is to enable formation of an acoustic resonator using a high quality piezoelectric body.

### Solution to Problem

An acoustic resonator according to embodiments of the present invention includes a first electrode made of a semiconductor doped with impurities; a piezoelectric body made of a piezoelectric semiconductor formed on the first electrode; and a second electrode formed on the piezoelectric body.

A modulator according to embodiments of the present invention includes a first electrode made of a semiconductor doped with impurities; a piezoelectric body made of a piezoelectric semiconductor formed on the first electrode; a second electrode formed on the piezoelectric body; and a semiconductor optical device stacked on the second electrode.

An acousto-optic modulator according to embodiments of the present invention includes a first electrode made of a semiconductor doped with impurities; a piezoelectric body made of a piezoelectric semiconductor formed on the first electrode; a second electrode formed on the piezoelectric body; and an acousto-optic medium stacked on the first electrode or the second electrode.

An acousto-optic modulator according to embodiments of the present invention includes a first electrode made of a semiconductor doped with impurities; a piezoelectric body made of an acousto-optic medium formed on the first electrode; and a second electrode formed on the piezoelectric body.

### Advantageous Effects

As described above, according to embodiments of the present invention, since the piezoelectric body made of a piezoelectric semiconductor is formed on the first electrode made of a semiconductor doped with impurities, an acoustic resonator made of a high quality piezoelectric body can be formed.

### BRIEF DESCRIPTION OF THE DRAWINGS

FIG. 1 is a sectional view showing a configuration of an acoustic resonator according to Embodiment 1 of the present invention.

FIG. 2 is a sectional view showing a configuration of another acoustic resonator according to Embodiment 1 of the present invention.

FIG. 3A is a characteristic diagram showing a bulk acoustic resonance mode generated by applying a high frequency to the acoustic resonator according to Embodiment 1 of the present invention.

FIG. 3B is a characteristic diagram showing a bulk acoustic resonance mode generated by applying a high frequency to the acoustic resonator according to Embodiment 1 of the present invention.

FIG. 3C is a characteristic diagram showing a relationship between the thickness of a piezoelectric body 102 and the center frequency that can be excited.

FIG. 4 is a sectional view showing a configuration of a modulator according to Embodiment 2 of the present invention.

FIG. 5 is a sectional view showing a configuration of an acousto-optic modulator according to Embodiment 3 of the present invention.

### DETAILED DESCRIPTION OF ILLUSTRATIVE EMBODIMENTS

An acoustic resonator according to an embodiment of the present invention will be described below.

### Embodiment 1

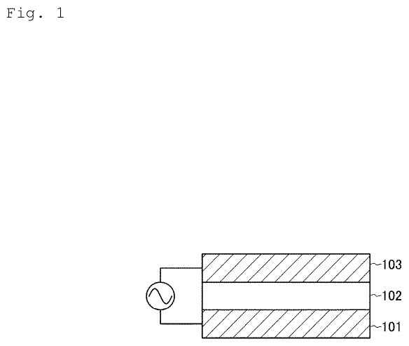

First, an acoustic resonator according to Embodiment 1 of the present invention will be described with reference to FIG. 1. This acoustic resonator includes a first electrode 101, a piezoelectric body 102, and a second electrode 103. The first electrode 101 is made of a semiconductor doped with impurities. The piezoelectric body 102 is made of a piezoelectric semiconductor and is formed on the first electrode 101. The piezoelectric semiconductor is, for example, a nitride semiconductor. The second electrode 103 is formed on the piezoelectric body 102. The second electrode 103 can be made of a metal or a semiconductor doped with impurities.

The piezoelectric body 102 is sandwiched between the first electrode 101 and the second electrode 103, for example, the piezoelectric body 102 is formed on and in contact with the first electrode 101, and the second electrode 103 is formed on and in contact with the piezoelectric body 102. By applying a high frequency voltage between the first electrode 101 and the second electrode 103, it is possible to generate acoustic vibrations corresponding to the frequency of the applied high frequency voltage.

For example, the piezoelectric body 102 can be formed by epitaxially growing a piezoelectric semiconductor on the first electrode 101. When the second electrode 103 is made of a metal, the second electrode 103 can be formed by depositing a metal material on the piezoelectric body 102 using a sputtering method or the like. Further, when the second electrode 103 is a semiconductor, the second electrode 103 can be formed by growing the semiconductor on the piezoelectric body 102 using a well-known CVD method or the like.

For example, the first electrode 101 can be made of n-type silicon carbide doped with N as an impurity. Furthermore, the piezoelectric body 102 can be made of aluminum nitride (AlN). Furthermore, the second electrode 103 can be made of Ti and Al. An acoustic resonator can be obtained by epitaxially growing a c-axis oriented aluminum nitride on the first electrode 101 made of n-type silicon carbide using a known metal organic vapor deposition (MOCVD) method to form the piezoelectric body 102 having a thickness of 700 nm, and depositing Ti and Al on the piezoelectric body 102 to form the second electrode 103.

The first electrode 101 is floatingly grounded or grounded. In the case of grounding, an ohmic electrode can also be produced by forming a film of a metal such as Ni or Ti that forms an alloy with silicon carbide on the ground plane of the first electrode 101 and then heat-treating it at a temperature of 800° C. to 1200° C. The thickness of the n-type silicon carbide substrate used as the first electrode 101 is 244 μm, but it can be made thinner by polishing or etching. It is also possible to increase the thickness by using substrates with different thicknesses.

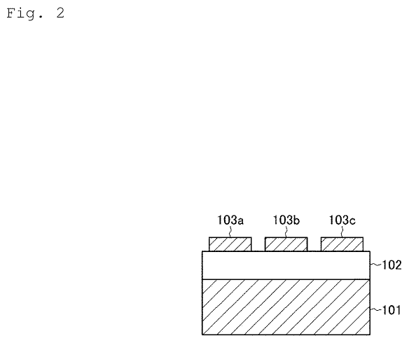

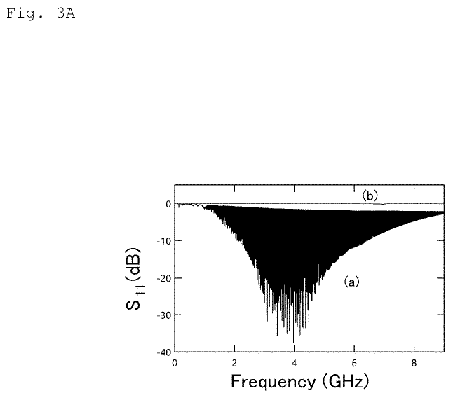

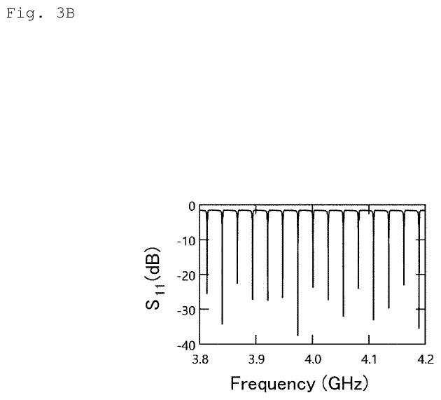

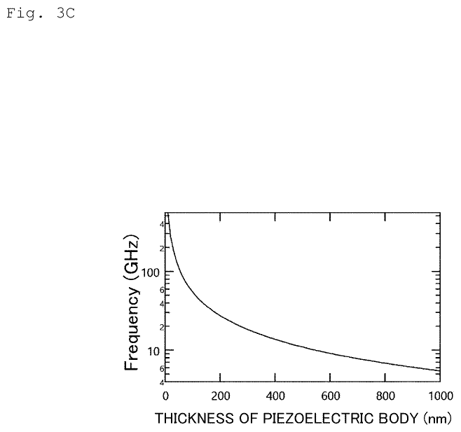

When the first electrode 101 is floatingly grounded or grounded as described above, as shown in FIG. 2, three second electrodes 103a, 103b, and 103c are formed on the piezoelectric body 102, the second electrode 103a and the second electrode 103c are used as ground terminals, the second electrode 103b is used as a signal terminal, and a high frequency GSG probe is electrically connected to these. When a high frequency is applied in this state, a bulk acoustic resonance mode centered around 4 GHz is obtained, as shown in (a) of FIG. 3A.

Further, as shown in FIG. 3B, which is a partially enlarged view of FIG. 3A, a cavity mode having a peak at every 26.8 MHz is observed. This frequency interval corresponds to the acoustic modes that propagate back and forth through the bulk acoustic resonator. This experimental result is obtained by applying a high frequency voltage between the second electrodes 103a, 103b, and 103c and the first electrode 101 made of n-type silicon carbide, this shows that the piezoelectric body 102 vibrates through an inverse piezoelectric effect of the piezoelectric body 102 made of AlN, and this vibration propagates through the first electrode 101. This result shows that a bulk acoustic resonator is realized by forming the first electrode 101 from n-type silicon carbide and forming the piezoelectric body 102 from AlN.

On the other hand, in a configuration in which a non-doped silicon carbide substrate is used, a piezoelectric body is formed by epitaxially growing AlN on this substrate, and a metal electrode is further formed on this substrate, as shown in (b) of FIG. 3A, it was confirmed that no bulk acoustic resonance mode was generated. This result shows that it is essential that the first electrode be formed of a doped semiconductor layer.

Note that the piezoelectric body 102 can be made of a piezoelectric semiconductor such as AlN, AlₓGa₁₋ₓN (0<x<1), GaN, ScₓAl₁₋ₓN (0<x<1), and ScₓGa₁₋ₓN (0<x<1). When Sc is included, the crystal structure changes from a hexagonal crystal to a cubic crystal as the composition x increases. In the case of a cubic crystal structure, the inverse piezoelectric effect can be maximized by forming a (111) oriented piezoelectric semiconductor.

Here, the relationship among a center frequency f_{c} that can be excited, a thickness t of the piezoelectric semiconductor, and a sound velocity vL of the longitudinal wave is expressed by the formula “f_{c}=vL/(2t)·n (n is an odd number).” For example, when the piezoelectric body 102 is made of AlN, the relationship between the thickness of the piezoelectric body 102 and the center frequency that can be excited is as shown in FIG. 3C. The center frequency that can be excited can also be adjusted by the second electrode 103. Note that FIG. 3A is the result of an acoustic resonator in which the second electrode 103 made of a metal is formed on the piezoelectric body 102, and therefore is different from the result of FIG. 3C for a single piezoelectric semiconductor.

It is also apparent from experiments that the center frequency that can be excited can be changed by changing the effective area of the acoustic resonator.

According to Embodiment 1, since the piezoelectric semiconductor is epitaxially grown on the first electrode 101 made of a semiconductor doped with impurities, the piezoelectric body 102 can be made of a high quality piezoelectric semiconductor. As a result, it is possible to improve the Q value, piezoelectric coefficient, and electromechanical coupling constant. Furthermore, since this type of epitaxial growth is performed in a film formation chamber under reduced pressure, it is possible to prevent foreign matter from entering or generating cavities at the interface between the first electrode 101 and the piezoelectric body 102.

Further, according to Embodiment 1, since the first electrode 101 is the substrate on which the piezoelectric semiconductor to be used as the piezoelectric body 102 is grown, there is no need to separately form electrodes made of a metal, and the manufacturing process of the acoustic resonator can be simplified.

By the way, when the second electrode 103 is made of an impurity-doped semiconductor and the piezoelectric body 102 is made of a nitride semiconductor, a transparent acoustic resonator can be formed. Examples of piezoelectric semiconductors include AlN, AlₓGa₁₋ₓN (0<x<1), GaN, ScₓAl₁₋ₓN (0<x<1), and ScₓGa₁₋ₓN (0<x<1). Further, the first electrode 101 and the second electrode 103 can be made of doped-AlN, doped-AlGaN, doped-GaN, or the like. These materials can be combined in various ways.

By using a transparent acoustic resonator, interactions between acoustic modes and, for example, charges, spins, elastic waves, excitons, and color centers in the crystal can be observed in detail optically.

Furthermore, by configuring the first electrode 101, the piezoelectric body 102, and the second electrode 103 from the same type of nitride semiconductor, it is possible to create an acoustic resonator with perfect acoustic impedance matching, allowing highly efficient acoustic mode propagation. For example, the first electrode 101/piezoelectric body 102/second electrode 103 can be made of doped-GaN/GaN/doped-GaN, doped-AlN/AlN/doped-AlN, doped-AlGaN/AlGaN/doped-AlGaN, or the like.

### Embodiment 2

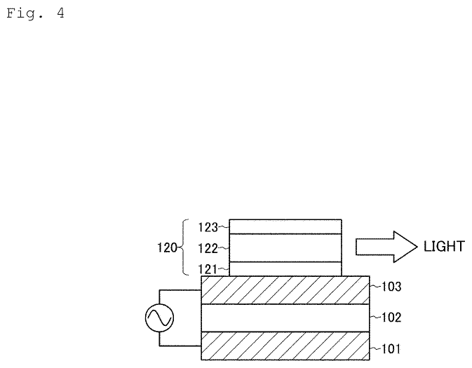

Next, a modulator according to Embodiment 2 of the present invention will be described with reference to FIG. 4. This modulator includes a first electrode 101 made of a semiconductor doped with impurities, a piezoelectric body 102 made of a piezoelectric semiconductor formed on the first electrode 101, a second electrode 103 formed on the piezoelectric body 102, and a semiconductor optical device 120 stacked on the second electrode 103.

For example, the semiconductor optical device 120, which is a semiconductor laser, can be formed by sequentially epitaxially growing a first semiconductor layer 121 made of an n-type semiconductor, an active layer 122 made of a semiconductor, and a second semiconductor layer 123 made of a p-type semiconductor on the second electrode 103 made of a semiconductor doped with impurities.

The acoustic resonator formed by the first electrode 101, the piezoelectric body 102, and the second electrode 103 modulates the energy band in the active layer 122 of the semiconductor optical device 120, thereby making it possible to modulate the laser output. The acoustic resonator and the semiconductor optical device 120 can be integrated into a modulator, and the modulator can be made smaller and more efficient. Further, by making the piezoelectric body 102 thinner, high frequency modulation can be achieved. Furthermore, by configuring the piezoelectric body from a nitride semiconductor, the acoustic mode can be made to have a high frequency due to its high sound velocity, and at the same time, the wavelength of a laser beam can be shortened due to its wide bandgap.

### Embodiment 3

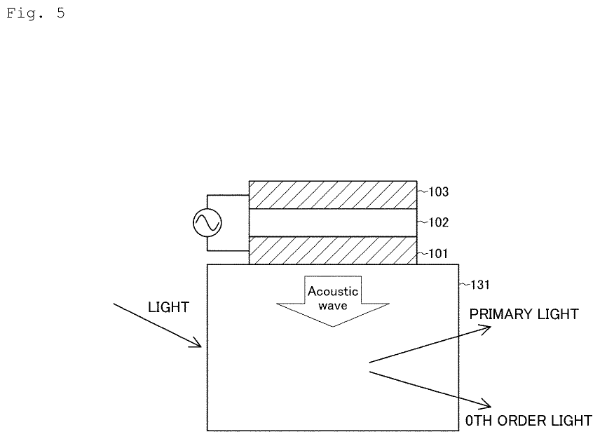

Next, an acousto-optic modulator according to Embodiment 3 of the present invention will be described with reference to FIG. 5. This acousto-optic modulator includes a first electrode 101, a piezoelectric body 102 formed on the first electrode 101, a second electrode 103 formed on the piezoelectric body 102, and an acousto-optic medium 131 stacked on the first electrode 101 or the second electrode 103. The acousto-optic medium 131 can be made of crystals such as gallium phosphide, tellurium dioxide, indium phosphide, quartz, and germanium.

In this example, the first electrode 101 is stacked on the acousto-optic medium 131 in the state of being in contact with the first electrode 101. For example, by pasting the first electrode 101 of the acoustic resonator and the acousto-optic medium 131, an acousto-optic modulator can be obtained. The acoustic resonator serves as a high frequency transducer.

High frequency bulk acoustic waves generated from the acoustic resonator propagate through the acousto-optic medium 131. The refractive index of the acousto-optic medium 131 is periodically modulated by the propagating bulk acoustic wave. When a laser beam is incident on the acousto-optic medium 131 whose refractive index is periodically modulated in this way, it is diffracted due to the periodic change in the refractive index, and a laser beam whose frequency is shifted by the frequency of the bulk acoustic wave is output.

Note that by configuring the piezoelectric body 102 from an acousto-optic medium, the same effects as described above can be obtained using the acoustic resonator alone.

As described above, according to embodiments of the present invention, since the piezoelectric body made of a piezoelectric semiconductor is formed on the first electrode made of a semiconductor doped with impurities, an acoustic resonator made of a high quality piezoelectric body can be formed.

Note that the present invention is not limited to the embodiment described above, and it is obvious that many modifications and combinations can be implemented by a person having ordinary knowledge in the art within the technical idea of the present invention.

Reference Signs List

| | |
|---|---|
| 101 | First electrode |
| 102 | Piezoelectric body |
| 103 | Second electrode |

1-6. (canceled)

7. An acoustic resonator comprising:
a first electrode made of a semiconductor doped with impurities;
a piezoelectric body made of a piezoelectric semiconductor, the piezoelectric body directly contacting the first electrode; and
a second electrode on the piezoelectric body.

8. The acoustic resonator according to claim 7, wherein the piezoelectric semiconductor is a nitride semiconductor.

9. The acoustic resonator according to claim 7, wherein the second electrode is made of a metal.

10. The acoustic resonator according to claim 7, wherein the second electrode is made of a semiconductor doped with impurities.

11. The acoustic resonator according to claim 7, wherein the semiconductor of the first electrode is an n-type silicon carbide, and wherein the impurities of the first electrode are nitrogen impurities.

12. A modulator comprising:
a first electrode made of a semiconductor doped with impurities;
a piezoelectric body made of a piezoelectric semiconductor, the piezoelectric body being in direct contact with the first electrode;
a second electrode on the piezoelectric body; and
a semiconductor optical device stacked on the second electrode.

13. The modulator according to claim 12, wherein the semiconductor optical device is a semiconductor laser.

14. The modulator according to claim 13, wherein the semiconductor laser comprises:
an n-type semiconductor in direct contact with the second electrode;
an active layer on the n-type semiconductor; and
an p-type semiconductor on the active layer.

15. The modulator according to claim 14, wherein the second electrode is made of a semiconductor doped with impurities.

16. The modulator according to claim 12, wherein the piezoelectric semiconductor is a nitride semiconductor.

17. The modulator according to claim 12, wherein the semiconductor of the first electrode is an n-type silicon carbide, and wherein the impurities of the first electrode are nitrogen impurities.

18. An acousto-optic modulator comprising:
a first electrode made of a semiconductor doped with impurities;
a piezoelectric body made of a piezoelectric semiconductor, the piezoelectric body being in direct contact with the first electrode;
a second electrode on the piezoelectric body; and
an acousto-optic medium stacked on the first electrode or the second electrode.

19. The acousto-optic modulator according to claim 18, wherein the acousto-optic medium is made of gallium phosphide, tellurium dioxide, indium phosphide, quartz, or germanium crystals.

20. The acousto-optic modulator according to claim 18, wherein the first electrode is pasted to the acousto-optic medium.

21. The acousto-optic modulator according to claim 18, wherein the semiconductor of the first electrode is an n-type silicon carbide, and wherein the impurities of the first electrode are nitrogen impurities.
